(19) United States
(12) Patent Application Publication
(10) Pub. No.: US 2006/0180804 A1
(43) Pub. Date: Aug. 17, 2006

(54) Thin-film semiconductor component and production method for said component

(76) Inventors: Peter Stauss, Pettendorf (DE); Andreas Ploessl, Regensburg (DE)

Correspondence Address: COHEN, PONTANI, LIEBERMAN & PAVANE, 551 FIFTH AVENUE, SUITE 1210, NEW YORK, NY, 10176, US

(21) Appl. No.: 10/544,159

(22) PCT Filed: Jan. 27, 2004
(86) PCT No.: PCT/DE04/00121

§ 371 Date: Mar. 13, 2006

(30) Foreign Application Priority Data
Jan. 31, 2003 (DE) 103 03 978.3

(51) Int. Cl. H01L 29/06

(52) U.S. Cl. 257/11

(57) ABSTRACT

A semiconductor component having a thin-film semiconductor body (2) arranged on a germanium-containing carrier (4). A method for producing such a semiconductor component includes producing a semiconductor component having a thin-film conductor body arranged on a carrier, having the steps of growing the thin-film semiconductor body on a substrate, applying the carrier to a side of the thin-film semiconductor body that is remote from the substrate, and stripping the thin-film semiconductor body from the substrate, wherein the carrier contains germanium.

The invention relates to a semiconductor component according to the preamble of patent claim 1 and to a production method for said component according to the preamble of patent claim 13.

Semiconductor components of the aforementioned type contain a thin-film semiconductor body and a carrier, on which the semiconductor body is fixed.

Thin-film semiconductor bodies are used, for example, in optoelectronic components in the form of thin-film luminescence diode chips. A thin-film luminescence diode chip is distinguished in particular by the following characteristic features:
a reflective layer is applied or formed at a first main area of a radiation-generating epitaxial layer sequence that faces toward a carrier element, said reflective layer reflecting at least a part of the electromagnetic radiation generated in the epitaxial layer sequence back into the latter;
a thin-film luminescence diode chip is to a good approximation a Lambert surface radiator;
the epitaxial layer sequence has a thickness in the region of 20 μm or less, in particular in the region of 10 μm; and
the epitaxial layer sequence contains at least one semiconductor layer with at least one area having an intermixing structure which ideally leads to an approximately ergodic distribution of the light in the epitaxial layer sequence, i.e. it has an as far as possible ergodically stochastic scattering behavior.

A basic principle of a thin-film luminescence diode chip is described for example in I. Schnitzer et al., Appl. Phys. Lett. 63 (16), Oct. 18 1993, 2174-2176, the disclosure content of which is in this respect hereby incorporated by reference. It should be noted that although the present invention relates particularly to thin-film luminescence diode chips, it is not restricted to the latter. Rather, the present invention is suitable not only for thin-film luminescence diode chips but also for all other thin-film semiconductor bodies.

In order to produce a thin-film semiconductor, firstly a semiconductor layer is fabricated on a suitable substrate, subsequently connected to the carrier and then stripped from the substrate. By dividing up, for example sawing up, the carrier with the semiconductor layer arranged thereon, a plurality of semiconductor bodies arise which are in each case fixed on the corresponding carrier.

What is essential in this case is that the substrate used for producing the semiconductor layer is removed from the semiconductor layer and does not simultaneously serve as a carrier in the component.

This production method has the advantage that different materials can be used for the substrate and the carrier. This means that the respective materials can be adapted to the different requirements for the production of the semiconductor layer, on the one hand, and the operating conditions, on the other hand, largely independently of one another. Thus, the carrier can be optimized in accordance with its mechanical, thermal and optical properties, while the substrate is chosen in accordance with the requirements for fabricating the semiconductor layer.

In particular the epitaxial production of a semiconductor layer makes numerous special requirements of the epitaxial substrate. By way of example, the lattice constants of the epitaxial substrate and of the semiconductor layer to be applied have to be matched to one another. Furthermore, the substrate should withstand the epitaxy conditions, in particular temperatures up to more than 1000° C., and be suitable for the epitaxial accretion and growth of an as far as possible homogeneous layer of the relevant semiconductor material.

By contrast, other properties of the carrier such as, by way of example, a high electrical and thermal conductivity and also radiation transmissivity in the case of optoelectronic components come to the fore for the further processing of the semiconductor body and operation. Therefore, the materials suitable for an epitaxial substrate are often only suitable to a limited extent as a carrier in the component. Finally, it is desirable, particularly in the case of comparatively expensive epitaxial substrates, to be able to use the substrates repeatedly.

The stripping of the semiconductor layer from the epitaxial substrate may be achieved, for example, by irradiating the semiconductor-substrate interface with laser radiation. In this case, the laser radiation is absorbed in the vicinity of the interface, where it effects a temperature increase up to the decomposition of the semiconductor material. A method of this type is disclosed in the document WO 98/14986, for example. The method described therein for stripping GaN and GaInN layers from a sapphire substrate uses the frequency-tripled radiation of a Q-switched Nd:Yag laser at 355 nm. The laser radiation is radiated in through the transparent sapphire substrate onto the semiconductor layer and is absorbed in a boundary layer having a thickness of approximately 100 nm at the junction between the sapphire substrate and the GaN semiconductor layer. In this case, such high temperatures are reached at the interface that the GaN boundary layer decomposes, and the bond between the semiconductor layer and the substrate is consequently separated.

A Gallium arsenide substrate (GaAs substrate) is often used as a carrier in conventional methods. However, toxic arsenic-containing waste arises during the processing, for example during the sawing of GaAs substrates, and requires correspondingly costly disposal. Added to this is the fact that GaAs substrates have to have a specific minimum thickness in order to ensure a sufficient mechanical stability for the production method mentioned above. This may necessitate thinning, for example grinding away the carrier after the application of the semiconductor layer and the stripping from the epitaxial substrate, thereby increasing the effort in production and the risk of a fracture in the carrier.

It is an object of the present invention to provide a thin-film component of the type mentioned in the introduction with an improved carrier. In particular, this component is intended to be able to be produced technically as simply and cost-effectively as possible. Furthermore, it is an object of the invention to specify a corresponding production method.

This object is achieved by means of a component in accordance with Patent claim 1 and a production method in accordance with Patent claim 11. The dependent claims relate to advantageous developments of the invention.

The invention provides for forming a semiconductor component having a thin-film semiconductor body arranged on a carrier containing germanium. A germanium substrate is preferably used as the carrier. Said carrier is referred to hereinafter as “germanium carrier” for short.

The thin-film semiconductor body is to be understood as a substrateless semiconductor body in the context of the invention, that is to say an epitaxially fabricated semiconductor body from which the epitaxial substrate on which the semiconductor body was originally grown is removed.

For fixing purposes, the semiconductor body may, for example, be adhesively bonded onto the germanium carrier. A soldering connection is preferably formed between the thin-film semiconductor body and the carrier. Such a soldering connection generally has a higher thermal loading capacity and a better thermal conductivity compared with adhesive bonds. Furthermore, by means of a soldering connection, a connection exhibiting good electrical conductivity is produced between the carrier and the semiconductor body without any additional outlay, which connection may simultaneously serve for making contact with the semiconductor body.

Germanium carriers are significantly easier to process compared with arsenic-containing carriers, in particular no toxic arsenic-containing waste arising. The overall effort during production is thus reduced. Furthermore, germanium carriers are distinguished by a higher mechanical stability which makes it possible to use thinner carriers and, in particular to dispense with subsequent grinding away of the carrier for thinning. Finally, germanium carriers are significantly more cost-effective than comparable GaAs carriers.

In a further aspect of the invention, the thin-film semiconductor body is soldered onto the germanium carrier. A gold-germanium soldering connection is preferably formed for this purpose. A fixed, thermally stable connection exhibiting good electrical and thermal conductivity is thus achieved. Since the melting point of the gold-germanium connection that arises is greater than the temperatures that usually arise during the mounting of a finished component, for example the soldering onto a printed circuit board, it need not be feared that the semiconductor body will be stripped away from the carrier during mounting.

The invention is particularly suitable for semiconductor bodies based on III-V compound semiconductors, which are to be understood in particular as the compounds AlₓGa₁₋ₓAs where 0≦x≦1, InₓAl_{y}Ga_{1-x-y}P, InₓAs_{y}Ga_{1-x-y}P, InₓAl_{y}Ga_{1-x-y}As, InₓAl_{y}Ga_{1-x-y}N, in each case where 0≦x≦1, 0≦y≦1, 0≦x+y≦1, and also InₓGa₁₋ₓAs_{1-y}N_{y} where 0≦x≦1, 0≦y≦1.

Sapphire or silicon carbide substrates are often used for the epitaxial production of the aforementioned nitride compound semiconductor InₓAl_{y}Ga_{1-x-y}N. Since sapphire substrates, on the one hand, are electrically insulating and thus do not enable vertically conductive component structures and silicon carbide substrates, on the other hand, are comparatively expensive and brittle and thus require complicated processing, the further processing of nitride-based semiconductor bodies as thin-film semiconductor bodies, that is to say without an epitaxial substrate, is particularly advantageous.

In the case of a method according to the invention for producing a semiconductor component having a thin-film semiconductor body, firstly the thin-film semiconductor body is grown on a substrate, afterward a germanium carrier such as a germanium wafer, for example, is applied to that side of the carrier which is remote from the substrate, and then the thin-film semiconductor body is stripped from the substrate.

The thin-film semiconductor body is preferably soldered onto the carrier. For this purpose, a gold layer is applied for example to the carrier and the thin-film semiconductor body, in each case on the connection side. These gold layers are subsequently brought into contact, pressure and temperature being chosen such that a gold-germanium melt arises which solidifies to form a gold-germanium eutectic. As an alternative, the gold layer may also be applied only on the carrier or the thin-film semiconductor body. It is also possible to apply a gold-germanium alloy instead of the gold layer or the gold layers. Since the carrier itself contains germanium, alloying problems such as may occur in the case of GaAs substrates are avoided, on the one hand. On the other hand, the germanium carrier constitutes a germanium reservoir with regard to the gold-germanium melt, said germanium reservoir facilitating the formation of the eutectic.

In the case of the invention, the substrate may be eroded by means of a grinding or etching method. These steps are preferably combined, such that the substrate is firstly ground away to a thin residual layer, and the residual layer is subsequently etched away. An etching method is particularly suitable for semiconductor layers based on InₓAl_{y}Ga_{1-x-y}P or InₓAs_{y}Ga_{1-x-y}P which are grown on a GaAs epitaxial substrate. In this case, the etching depth is expediently set by means of an etching stop, so that the GaAs epitaxial substrate is etched away as far as the semiconductor layers based on InₓAl_{y}Ga_{1-x-y}P or InₓAs_{y}Ga_{1-x-y}P.

In the case of semiconductor layers based on nitride compound semiconductors, the substrate is preferably stripped away by laser irradiation. In this case, the substrate-semiconductor interface is irradiated with laser radiation through the substrate. The radiation is absorbed in the vicinity of the interface between a semiconductor layer and substrate, where it leads to a temperature increase up to the decomposition of the semiconductor material, the substrate being detached from the semiconductor layer. A Q-switched Nd:YAG laser with frequency tripling or an excimer laser which emits in the ultraviolet spectral range, for example, is preferably used for this purpose. A pulsed operation of the excimer laser is expedient for achieving the required intensity. Pulse durations of less than or equal to 10 ns have generally proved to be advantageous.

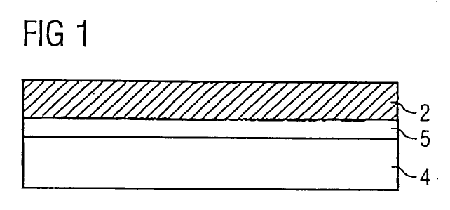

Further features, advantages and expediencies of the invention emerge from the exemplary embodiments described below in conjunction with FIGS. 1 to 3.

In the figures:

FIG. 1 shows a schematic illustration of an exemplary embodiment of a semiconductor component according to the invention.

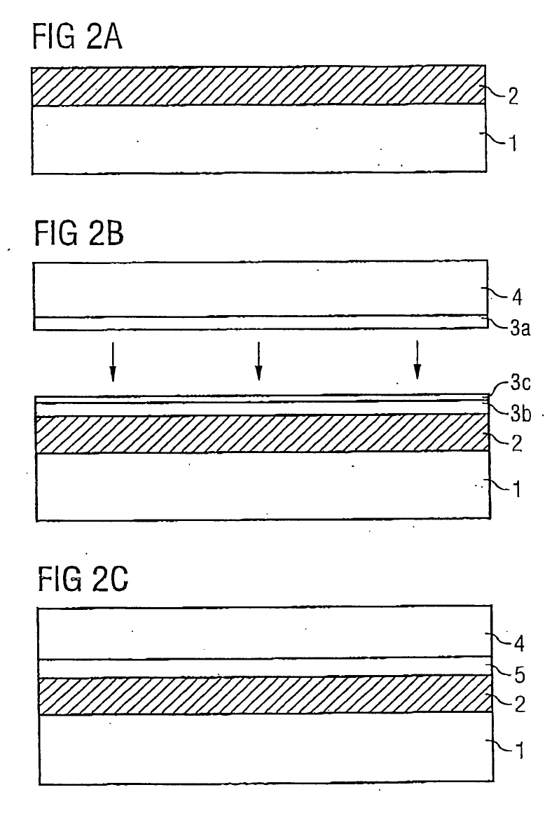

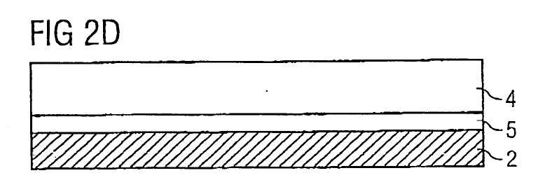

FIGS. 2A to 2D show a schematic illustration of a first exemplary embodiment of a production method according to the invention on the basis of four intermediate steps, and

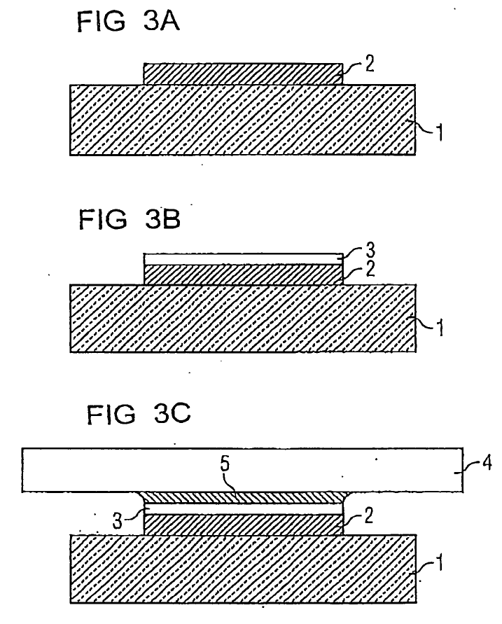

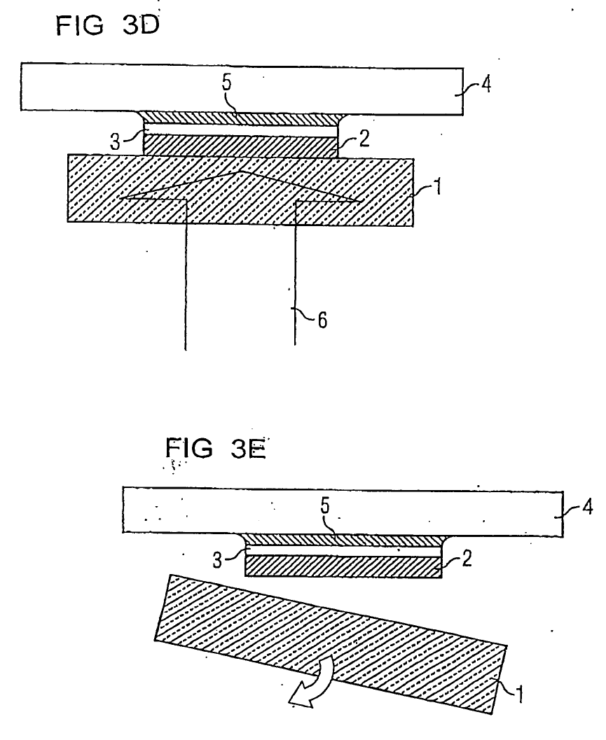

FIGS. 3A to 3E show a schematic illustration of a second exemplary embodiment of a production method according to the invention on the basis of five intermediate steps.

Identical or identically acting elements are provided with the same reference symbols in the figures.

The semiconductor component illustrated in FIG. 1 has a carrier 4 in the form of a germanium substrate, on which a thin-film semiconductor body 2 is fixed by means of a solder layer 5. The thin-film semiconductor body 2 preferably comprises a plurality of semiconductor layers that were initially grown on an epitaxial substrate (not illustrated) which was removed after the semiconductor body had been applied to the carrier 4.

The embodiment as a thin-film component is suitable in particular for radiation-emitting semiconductor bodies since an absorption of the radiation generated and thus a reduction of the radiation efficiency in the epitaxial substrate are avoided. By way of example, the semiconductor layers may be arranged in the form of a radiation-generating pn junction which may furthermore contain a single or multiple quantum well structure.

In the case of the invention, a mirror layer is preferably arranged between the radiation-emitting layer of the thin-film semiconductor body and the germanium carrier. Said mirror layer reflects the radiation components emitted in the direction of the germanium carrier and thus increases the radiation efficiency. The mirror layer is furthermore preferably embodied as a metallic layer which, in particular, may be arranged between the layer formed by the soldering connection and the thin-film semiconductor body. Highly reflective mirrors may be formed for example by arranging on the thin-film semiconductor body firstly a dielectric layer and then the preferably metallic mirror layer, the mirror layer expediently being partially interrupted for the purpose of making electrical contact with the thin-film semiconductor body.

In an advantageous manner, conventional components and methods with GaAs as carrier material can be adopted largely unchanged in the case of the invention, a germanium carrier being used instead of the GaAs carrier. Since the coefficient of thermal expansion of germanium is similar to the coefficient of thermal expansion of gallium arsenide it is generally possible to exchange conventional GaAs substrates for germanium substrates without any additional outlay during production and without impairing the component properties. By contrast, germanium is distinguished by a somewhat higher thermal conductivity than gallium arsenide.

As already described, germanium substrates are furthermore advantageous on account of their low price, their easier processability and their comparatively high mechanical stability. Thus, by way of example, GaAs substrates having a thickness of more than 600 μm can be exchanged for germanium substrates having a thickness of 200 μm, whereby subsequent thinning of the substrate can be obviated.

Furthermore, germanium is advantageous with regard to the soldering connection 5 since this avoids alloying problems in the case of gallium arsenide in conjunction with gold-germanium metallizations.

In the first step of the method illustrated in FIG. 2, FIG. 2A, a semiconductor body 2 is applied to a substrate 1. In particular, the semiconductor body 2 may also contain a plurality of individual layers, for example based on InₓAl_{y}Ga_{1-x-y}P, which are grown successively on the substrate 1.

In the next step, FIG. 2B, the semiconductor body 2 is provided with a metallization 3a on the side remote from the substrate. A gold layer is preferably applied by vapor deposition.

Furthermore, a germanium carrier 4 is provided, to which a metallization 3b, preferably likewise a gold layer, is applied in a corresponding manner. These metallizations 3a, 3b on the one hand serve for forming the soldering connection between semiconductor body 2 and substrate 1 and on the other hand form an ohmic contact exhibiting good electrical conductivity. A gold-antimony layer 3c may optionally be applied to one of the gold layers 3a, 3b, antimony serving as n-type doping of the contact to be formed. Instead of antimony, arsenic or phosphorus may also be used for the doping. As an alternative, it is also possible to form a p-type contact, for example with an aluminum, gallium or indium doping.

As an alternative, in the context of the invention, it is also possible to use only one metallization 3a or 3b, which is applied either to the semiconductor body 2 or to the germanium carrier 4.

In the next step, FIG. 2C, the germanium carrier 4 and the substrate 1 with the semiconductor body 2 are joined together, temperature and pressure being chosen such that the metallization 3a, 3b, 3c melts and subsequently solidifies as a soldering connection. Preferably, firstly a gold-germanium melt forms in this case, which melt, upon cooling, forms a possibly antimony-doped gold-germanium eutectic as a soldering connection. In an advantageous manner, this melt can also encapsulate (accommodate) protrusions and other surface forms deviating from a plane, so that, in contrast to conventional methods, it is possible to depart from a plane-parallel melt front. By way of example, particles on the surface of the semiconductor body are thus encapsulated by the melt and embedded in the soldering connection.

In the final step, FIG. 2D, the substrate 1 is eroded away. For this purpose, by way of example, the substrate 1 is firstly ground away to a thin residual layer and the residual layer is subsequently etched away. A thin-film semiconductor body 2 soldered onto a germanium carrier 4 remains. As already explained, this method is advantageous in particular for InₓAl_{y}Ga_{1-x-y}P-based semiconductor bodies on GaAs epitaxial substrates.

In the case of the exemplary embodiment shown in FIG. 3, in contrast to the exemplary embodiment shown in FIG. 2, the substrate is removed by means of a laser stripping method.

In the first step, FIG. 3A, a semiconductor body 2, preferably based on a nitride compound semiconductor, is grown on a substrate 1. As in the previous exemplary embodiment, the semiconductor body 2 may comprise a plurality of individual layers and be formed as a radiation-emitting semiconductor body. With regard to the epitaxy and lattice matching of nitride compound semiconductors and also the laser stripping method, a sapphire substrate, in particular, is suitable as the substrate 1.

A metallization 3, preferably gold metallization, is applied to the surface of the semiconductor body, FIG. 3B, and the semiconductor body is then soldered to a germanium carrier 4, FIG. 3C. The soldering connection 5 is formed in accordance with the previous exemplary embodiment. As an alternative, as described in that case, it is also possible to provide two gold layers which are applied to the carrier, on the one hand, and to the semiconductor body on the other hand.

In the subsequent step, FIG. 3D, the semiconductor layer 2 is irradiated with a laser beam 6 through the substrate 1. The radiation energy is predominantly absorbed close to the interface between the semiconductor layer 2 and the substrate 1 in the semiconductor layer 2 and brings about a material decomposition at the interface, so that the substrate 1 can subsequently be lifted off.

In an advantageous manner, the strong mechanical loads occurring on account of the material decomposition are taken up by the solder layer, so that even semiconductor layers having a thickness of a few micrometers can be stripped non-destructively from the substrate.

An excimer laser, in particular an XeF excimer laser, or a Q-switched Nd:YAG laser with frequency tripling is advantageous as radiation source.

The laser radiation is preferably focussed onto the semiconductor layer 2 through the substrate by means of a suitable optical arrangement, so that the energy density on the semiconductor surface lies between 100 mJ/cm² and 1000 mJ/cm², preferably between 200 mJ/cm² and 800 mJ/cm². The substrate 1 can thus be lifted off from the semiconductor body in a manner free of residues, FIG. 3e. This type of separation advantageously enables the substrate to be reused as an epitaxial substrate.

It goes without saying that the explanation of the invention on the basis of the exemplary embodiments described does not constitute a restriction thereto. Rather, individual aspects of the exemplary embodiments can be combined with one another largely freely within the scope of the invention. Furthermore, the invention encompasses any new feature and also any combination of features, which comprises in particular any combination of features in the patent claims even if this combination is not specified explicitly in the patent claims.

1. A semiconductor component having a thin-film semiconductor body (2) arranged on a carrier (4),
wherein
the carrier (4) contains germanium.

2. The semiconductor component as claimed in claim 1,
wherein
the thin-film semiconductor body (2) is soldered onto the carrier (4).

3. The semiconductor component as claimed in claim 1,
wherein
the thin-film semiconductor body (2) is soldered onto the carrier (4) by means of a gold-containing solder.

4. The semiconductor component as claimed in claim 1 one of
wherein
the thin-film semiconductor body (2) comprises a plurality of individual layers.

5. The semiconductor component as claimed in claim 1,
wherein
the thin-film semiconductor body (2) or at least one of the individual layers contains a III-V compound semiconductor.

6. The semiconductor component as claimed in claim 5,
wherein
the thin-film semiconductor body (2) or at least one of the individual layers contains InₓAl_{y}Ga_{1-x-y}P, 0≦x≦1, 0≦y≦1, 0≦x+y≦1.

7. The semiconductor component as claimed in claim 5,
wherein
the thin-film semiconductor (2) or at least one of the individual layers contains InₓAs_{y}Ga_{1-x-y}P, 0≦x≦1, 0≦y≦1, 0≦x+y≦1.

8. The semiconductor component as claimed in claim 5,
wherein
the thin-film semiconductor body (2) or at least one of the individual layers contains InₓAl_{y}Ga_{1-x-y}Aₛ where 0≦x≦1, 0≦y≦1, 0≦x+y≦1 or InₓGa₁₋ₓAs_{1-y}N_{y} where 0≦x≦1, 0≦y≦1.

9. The semiconductor component as claimed in claim 5,
wherein
the thin-film semiconductor body (2) or at least one of the individual layers contains a nitride compound semiconductor, in particular InₓAl_{y}Ga_{1-x-y}N, 0≦x≦1, 0≦y≦1, 0≦x+y≦1.

10. The semiconductor component as claimed in claim 1,
wherein
the thin-film semiconductor body (2) has a radiation-emitting active region.

11. The semiconductor component as claimed in claim 1,
wherein
a mirror layer, preferably a metallic mirror layer, is arranged between the thin-film semiconductor body (2) and the carrier (4).

12. The semiconductor component as claimed in claim 11,
wherein
a dielectric layer is at least partially arranged between the thin-film semiconductor body (2) and the mirror layer.

13. A method for producing a semiconductor component having a thin-film conductor body (2) arranged on a carrier (4), having the steps of
a) growing the thin-film semiconductor body on a substrate,
b) applying the carrier (4) to a side of the thin-film semiconductor body (2) that is remote from the substrate (1), and
c) stripping the thin-film semiconductor body (2) from the substrate,
wherein
the carrier (4) contains germanium.

14. The method as claimed in claim 13,
wherein
the substrate is eroded, in particular ground away and/or etched away, in step c).

15. The method as claimed in claim 13,
wherein
the semiconductor body is stripped from the substrate (1) by laser irradiation in step c).

16. The method as claimed in claim 13,
wherein
the carrier is soldered on in step b).

17. The method as claimed in claim 13,
wherein
a gold layer (3, 3a, 3b) is arranged on that side of the thin-film semiconductor body (2) which faces the carrier and/or on that side of the carrier which faces the thin-film semiconductor body (2), and wherein said gold layer, when the carrier is soldered on in step b), at least partially forms a melt containing gold and germanium.

18. The method as claimed in claim 13,
wherein
prior to step b), a layer containing gold and germanium is applied on that side of the thin-film semiconductor body (2) which faces the carrier and/or on that side of the carrier which faces the thin-film semiconductor body (2).

19. The method as claimed in claim 13,
for producing a semiconductor component having a thin-film body arranged on a carrier that contains germanium.

20. The semiconductor component as claimed in claim 1, wherein the semiconductor component is a luminescence diode.

21. The semiconductor component as claimed in claim 20, wherein the semiconductor component is a light emitting diode or a laser diode.

22. The method as claimed in claim 13, wherein the semiconductor component is a luminescence diode.

23. The method as claimed in claim 22, wherein the semiconductor component is a light-emitting diode or a laser diode.
